(19) United States
(12) Patent Application Publication
(10) Pub. No.: US 2011/0114981 A1
(43) Pub. Date: May 19, 2011

(54) LIGHT EMITTING DISPLAY APPARATUS

(75) Inventors: Takuya Higaki, Chiba-shi (JP); Hiroyuki Kitayama, Isehara-shi (JP); Toshinori Hasegawa, Yokohama-shi (JP); Manabu Furugori, Mobara-shi (JP); Toshihide Kimura, Chiba-shi (JP)

(73) Assignee: CANON KABUSHIKI KAISHA, Tokyo (JP)

(21) Appl. No.: 13/000,611

(22) PCT Filed: Jun. 30, 2009
(86) PCT No.: PCT/JP2009/062266

§ 371 Date: Dec. 21, 2010

(30) Foreign Application Priority Data
Jun. 30, 2008 (JP) 2008-171745
Sep. 29, 2008 (JP) 2008-249881
Jun. 10, 2009 (JP) 2009-139375
Jun. 30, 2009 (JP) 2009-155044

(51) Int. Cl. H01L 51/52

(52) U.S. Cl. 257/98; 257/E51.018

(57) ABSTRACT

In a light emitting display apparatus, excellent color reproducibility and high luminance for an emission color having a low color purity and low emission efficiency are realized. An electroluminescent layer whose color purity and emission efficiency are to be improved is stacked as a first layer on a substrate, and is interposed between a reflective electrode layer and a semi-reflective electrode, and then light extracted from the electroluminescent layer is intensified by interference between a reflective surface in the reflective electrode layer and a reflective surface in the semi-reflective electrode.

### FIELD OF THE INVENTION

The present invention relates to a display apparatus utilizing a light emitting device using an organic compound, and more specifically, to a display apparatus using an organic electroluminescent (EL) device that emits light when an electric field is applied to a thin film made of an organic compound.

### BACKGROUND ART

The research and development of organic EL devices have been vigorously performed these days. Recently, the research and development of a high-resolution, multicolor display apparatus in which organic EL media are stacked and arrayed have been advanced in order that light beams of the respective colors may be emitted from a common area of the display apparatus.

Japanese Patent Application Laid-Open No. H10-503878 discloses an organic EL display apparatus capable of displaying multiple colors and formed as described below: an individual bias voltage can be input to each layer in order that each stacked body may emit light of each color.

U.S. Pat. No. 5,932,895 discloses a technique for optimizing the color purity and extraction efficiency of an organic light emitting apparatus in which a first electrode, a first organic compound layer, a second electrode, a second organic compound layer, a third electrode, a third organic compound layer, and a fourth electrode are stacked in the stated order from a light extraction side. To be specific, a reflective electrode is used as the fourth electrode, a transparent electrode is used as the third electrode, a half-reflective electrode is used as the second electrode, and the fourth electrode and the second electrode form a resonator.

Merely stacking multiple emission layers as in Japanese Patent Application Laid-Open No. H10-503878 involves the following problems: the color purity and extraction efficiency of the display apparatus cannot be optimized. In addition, when a resonator is formed by incorporating two organic compound layers as in U.S. Pat. No. 5,932,895, the order of interference increases because the optical path length of the resonator lengthens. As a result, the organic light emitting apparatus can obtain neither a sufficient color purity nor sufficient extraction efficiency. It is important for each of red, green, and blue light emitting devices to have an excellent color purity and high luminance in order that a full-color display apparatus showing good display performance may be realized. In particular, an improvement in performance of the blue light emitting device has been requested because the device is inferior in color purity and emission efficiency to the red and green light emitting devices.

### DISCLOSURE OF THE INVENTION

In order to achieve the above object, a light emitting display apparatus of the present invention includes:

a substrate;

multiple luminescence portions stacked on the substrate in a direction perpendicular to a surface of the substrate, the multiple luminescence portions each being interposed between a pair of electrodes; and

a light extraction portion for extracting light emitted from the luminescence portions, wherein:

one of the luminescence portion, which is placed farthest from the light extraction portion, is interposed between a reflective electrode and a semi-reflective electrode; and

an optical path length between the reflective electrode and the semi-reflective electrode is set such that light extracted outside the light emitting display apparatus, among lights emitted from the luminescence portion between the reflective electrode and the semi-reflective electrode, is intensified by interference.

According to the present invention, there is provided an organic light emitting display apparatus formed of organic EL devices in each of which multiple luminescence portions are stacked. In the organic light emitting display apparatus, an luminescence portion including an emission layer that emits light of a color whose color purity and extraction efficiency are to be improved is placed so as to be in contact with a reflective electrode, and a semi-reflective electrode is placed on the luminescence portion. Then, in order that the peak wavelength of light extracted from the emission layer may satisfy a resonance condition between the reflective electrode and the semi-reflective electrode, an optical path length between the electrodes is adjusted. As a result, the color purity and luminance of the light emitted from the luminescence portion provided so as to be in contact with the reflective electrode are improved, whereby the organic light emitting display apparatus becomes excellent in color reproducibility.

Further features of the present invention will become apparent from the following description of exemplary embodiments with reference to the attached drawings.

### BRIEF DESCRIPTION OF THE DRAWINGS

FIG. 1 is an outline sectional view illustrating a two-layer stacked organic EL display apparatus in the present invention.

FIG. 2 is an outline sectional view illustrating a two-layer stacked organic EL display apparatus in the present invention.

FIG. 3 is an outline sectional view illustrating an n-layer stacked organic EL display apparatus in the present invention.

FIG. 4 is an outline sectional view illustrating an example of the three-layer stacked organic EL display apparatus in the present invention.

### BEST MODE FOR CARRYING OUT THE INVENTION

FIG. 1 is an example of an outline partially enlarged sectional view of a top emission type, light emitting display apparatus using a two-layer stacked organic EL device as a display device.

The display apparatus is formed of two kinds of organic EL devices each having a stacked constitution. A first organic EL device is obtained by sequentially stacking, on a substrate 1, a reflective electrode 2, a first luminescence portion 3, a semi-reflective electrode 4, a second luminescence portion 5, and a light extraction electrode 6. A second stacked type organic EL device is obtained by sequentially stacking, on the substrate 1, the reflective electrode 2, a third luminescence portion 31, the semi-reflective electrode 4, a fourth luminescence portion 51, and the light extraction electrode 6. Those organic EL devices are covered with a protective layer 9.

Here, in the organic EL device, the reflective electrode is an electrode having a reflectance of 50% or more at a surface of the reflective electrode, the semi-reflective electrode is an electrode having a reflectance of 10% or more to less than 50%, and the transparent electrode is an electrode having 80% or more of transmittance with respect to a visible light.

The first luminescence portion has a first emission layer for emitting light of a first color, and the second luminescence portion has a second emission layer for emitting light of a second color. Similarly, the third luminescence portion has a third emission layer for emitting light of a third color, and the fourth luminescence portion has a fourth emission layer for emitting electroluminescence of a fourth color. The first to fourth colors are not requested to be different from one another, and a color emitted by an emission material having a short lifetime may be used duplicately. Each luminescence portion may have, for example, a hole injection layer (HIL), a hole transport layer (HTL), an electron transport layer (ETL), or an electron injection layer (EIL).

The substrate 1 in FIG. 1 is formed of a support 10, a TFT driver circuit 11, and a planarization passivation layer 12. Reference numeral 13 represents a contact hole. It should be noted that, in Examples, description is given by taking an active matrix driven display apparatus as an example, but a passive matrix driven display apparatus that does not require any TFT driver circuit is also permitted.

An electrode interposed between the luminescence portions like the semi-reflective electrode 4 may be provided as a single electrode common to both the luminescence portions between which the electrode is interposed. Alternatively, the following procedure may be adopted: an insulating layer is interposed between separately provided electrodes so that the respective luminescence portions can be independently driven.

When a current is flowed into each of those organic EL devices, a hole injected from an anode and an electron injected from a cathode recombine in each emission layer, so the emission layer emits its light.

FIG. 1 illustrates a top emission type display apparatus in which light is extracted from the side opposite to the substrate, a bottom emission type display apparatus in which emitted light is extracted from the side of the substrate 1, however, is also permitted. In the case of a bottom emission type display apparatus in which emitted light is extracted from the side of a support, replace a reflective electrode by the light extraction electrode 6, replace a transparent electrode by is the reflective electrode 2, and a transparent substance such as glass is used in the support 10 in the constitution illustrated in FIG. 1. provided that, when an active matrix driven display apparatus is desired, a display apparatus having a top emission constitution is advantageous from the viewpoint of the securement of an aperture ratio.

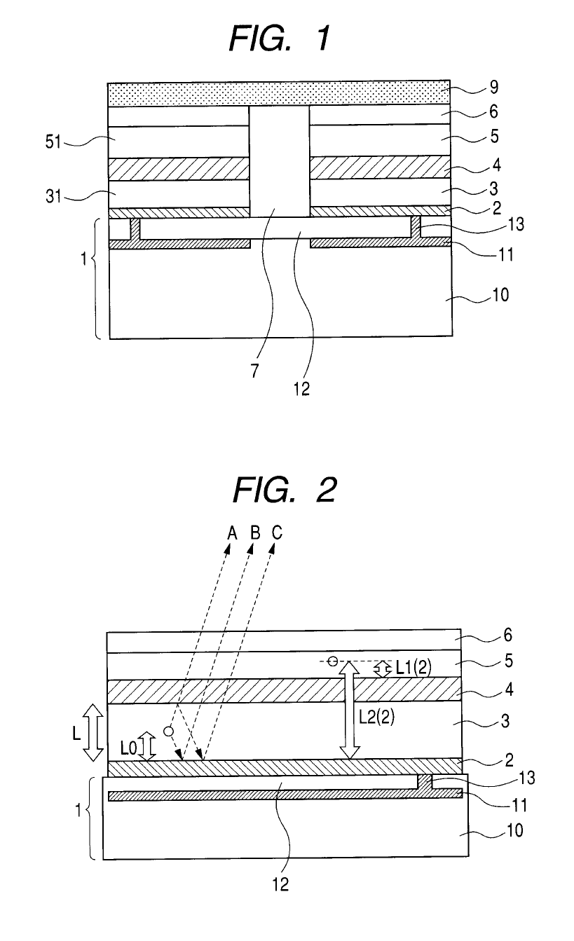

FIG. 2 is an example of an outline partially enlarged sectional view of a display apparatus using a (two-layer stacked) organic EL device in which two luminescence portions are stacked. Reference numerals identical to those of FIG. 1 represent members identical to those of FIG. 1; the same holds true for any other figure. The intensification of light beams by interference of the present invention is described by taking FIG. 2 as an example.

The intensification of light by interference is the following phenomenon: light with a wavelength λ having an emission spectrum (PL spectrum) peculiar to an emission material of which an emission layer is formed is reflected between two reflective surfaces, and the reflected light beams interfere with and intensify each other. The spectrum of light intensified by such interference and then extracted to the outside of the display apparatus has an intensity stronger than that of the PL spectrum at the wavelength λ. Subsequently, a specific example of the intensification by interference is described. When electroluminescence arises from the emission layer in the first luminescence portion 3 of FIG. 2, the light repeatedly undergoes, for example, reflection, refraction, transmission, and absorption owing to differences in refractive index and absorption coefficient between the respective layers of which the display apparatus is formed, and is then extracted to the outside. The quantity of the extracted light increases as a result of the interference and intensification of light beams that have passed through various paths.

Possible paths from the emission position of the first luminescence portion 3 are as follows: a light beam (A) that transmits through the semi-reflective electrode 4 to travel directly toward an extraction direction, and light beams (B) and (C) each of which is reflected at the first reflective surface of the reflective electrode 2 to travel toward the extraction direction. Here, any electrode placed closer to the light extraction side than the semi-reflective electrode 4 is preferably a transparent electrode in order that light emitted from each luminescence portion may be extracted while being prevented from reducing in quantity to the extent possible. Although, in actuality, light is reflected at any other interface between the respective layers as well, in the specification, reference is made only to the light beams along the paths A to C which may have a large influence on the extracted light.

As described above, an influence caused by the interference of the light beams A, B, and C is the largest. In particular, when the semi-reflective electrode is formed of, for example, a metal thin film, the wavelength at which the light beams intensify one another by interference can be controlled by adjusting an optical path length from the emission position to the reflective surface (first reflective surface) of the reflective electrode and an optical distance from the reflective surface of the reflective electrode to the reflective electrode-side reflective surface (second reflective surface) of the semi-reflective electrode.

In FIG. 2, L0 represents the optical path length between the emission position of the first luminescence portion 3 and the first reflective surface of the reflective electrode 2, and L represents the optical path length between the first reflective surface and the second reflective surface. Here, when the peak wavelength of the multiple beam interference spectrum of the emission layer, that is, the peak wavelength of the extracted light out of display apparatus, is represented by λ, the light with the wavelength λ can be efficiently extracted by appropriately adjusting the respective optical distances so that they may satisfy the following Equations (1) and (2) showing interference conditions:

m−0.1≦2L0/λ+δ/2π≦m+0.1 Eq. (1)

m′−0.1≦2L/λ+(δ+Φ)/2πm′+0.1 Eq. (2)

where m and m′ each represent a natural number.

In the Equations (1) and (2), when 2L0/λ+δ/2π=m and 2L/λ+(δ+Φ)/2π=m′ are satisfied, the highest intensification of light by interference can be obtained.

The Equations (1) and (2) are derived from conditions for the intensification by interference of an EL emission spectrum in a resonator in the document “Deppe J. Modern. Optics Vol. 41, No. 2, p. 325 (1994).”

In addition, phase shift amounts δ and Φ can each be calculated by using the n (refractive index) and k (absorption coefficient) of each of the reflective electrode and the semi-reflective electrode, and the refractive index n of an organic layer interposed between the pair of electrodes. The foregoing is described in, for example, “Principles of Optics, Max Born and Emil Wolf.” When the reflective electrode and the semi-reflective electrode described above are each formed of a metal film, the phase shift amounts δ and Φ by metal reflection can each be approximated to π radians, so the Equations (1) and (2) are changed into the following Equations (1)′ and (2)′.

(λ/4)·(2m−1.2)≦L0≦(λ/4)·(2m−0.8)(m: natural number) Eq. (1)′

(λ/2)·(m′−1.1)≦L≦(λ/2)·(m′−0.9)(m′: natural number) Eq. (2)′

Therefore, light beams most intensify each other by resonance when the optical path length L0 from the emission position to the reflective surface is an odd number multiple of λ/4 and the optical path length L from the reflective surface of the reflective electrode to the reflective surface of the semi-reflective electrode is a natural number multiple of λ/2.

It should be noted that the identification of an emission position (emission center) is needed in determining the values for the L0 and L. Although the emission position varies depending on a material to be used in each emission layer, the emission position can be roughly identified from the structures of a host material and a guest material to be used in the emission layer. In other words, the values for the L0 and L can be determined by defining the interface of the emission layer on the reflective electrode side or on the semi-reflective electrode side, or the center of the emission layer as the emission position depending on a material of which the emission layer is formed. When an emission intensity distribution is present in the thickness direction of the emission layer, the numerical values of L0 and L are preferably corrected as the maximum emission position is an emission position.

Although effect is smaller compared with when the Equations (1) and (2) are both satisfied, as for light emission at the luminescence portion disposed at the light extraction side closer to the semi-reflective electrode, light extraction efficiency can be improved using interference of a reflective light by the reflective electrode and a reflective light by the semi-reflective electrode.

In FIG. 2, the optical path length between the emission position in the second luminescence portion 5 and the reflective surface of the reflective electrode is L2(2), the optical path length between the emission position in the second luminescence portion 5 and the reflective surface at the light extraction side of the semi-reflective electrode is L1(2), and peak wavelength of light extracted from the emission layer contained the second luminescence portion is λ(2). Here, when thicknesses of the respective layers are designed so as to satisfy the following equations, light emission of λ(2) can be intensified and extracted. In the equations, k(2) and k′(2) are natural number.

k(2)−0.1≦2L1(2)/λ(2)+Φ/2π≦k(2)+0.1 Eq. (3)′

k′(2)−0.1≦2L2(2)/λ(2)+δ/2π≦k′(2)+0.1 Eq. (4)′

In the Equations (3)′ and (4)′, when 2L1(2)/λ(2)+Φ/2π=k(2) and 2L2 (2)/λ(2)+δ/2π=k′(2) are satisfied, the highest interference effect can be obtained. However, if the range is within the sign of inequality, sufficient interference effect may be obtained.

For example, in the configuration shown in FIG. 1, when color purity and luminance of blue are improved and the lifetime is lengthened, the following configuration is employed. That is, a blue emission layer is disposed in the first luminescence portion 3 of the first organic EL device; a green emission layer is disposed in the second luminescence portion 5 of the first organic EL device; a blue emission layer is disposed in the first luminescence portion 31 of the second organic EL device; a red emission layer is disposed in the second luminescence portion 51 of the second organic EL device; and thicknesses of the respective layers satisfy the Equations (1), (2), (3)′ and (4)′. In this case, in addition to improvement of color purity, luminance and lifetime of blue, luminance of red and green may be improved. Adjacent organic EL devices are preferably separated from each other by a pixel division layer 7. Materials used for the pixel division layer are not limited as long as the devices are separated and insulated. Taking account of reflection of outside light, a black material which absorbs light is preferable.

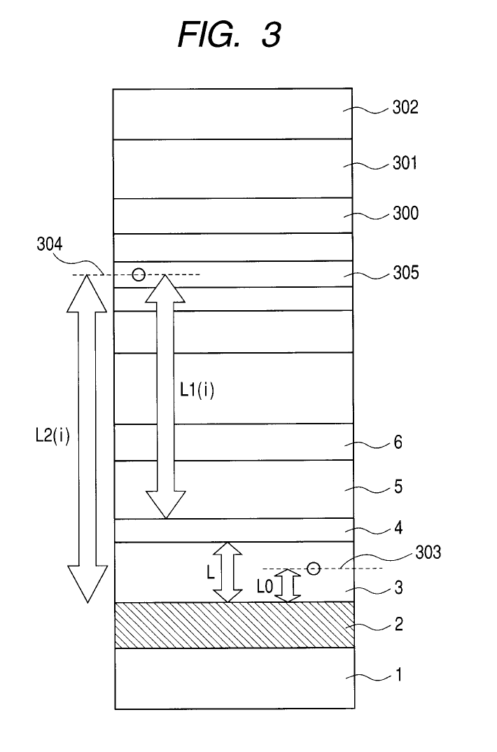

So far, two-layer stacked system has been described. However, organic EL devices of an n-layer stacked system may be designed in the same way. The foregoing is described with reference to an outline partially enlarged sectional view of a display apparatus using an n-layer stacked organic EL device (FIG. 3).

In FIG. 3, layers including the reflective electrode 2, the first luminescence portion 3, the semi-reflective electrode 4, the second luminescence portion 5, the third electrode 6, an n-th electrode 300, an n-th luminescence portion 301, and a light extraction electrode 302 are sequentially stacked in the stated order on the substrate 1. n represents a natural number of 2 or more. In addition, reference numeral 303 represents the emission position of the first luminescence portion, and reference numeral 304 represents the emission position of an i-th luminescence portion.

In this case, the reflective electrode 2, the first luminescence portion 3, and the semi-reflective electrode 4 are sequentially stacked to serve as a resonator for light emission from the first luminescence portion 3; the i-th luminescence portion 305 stacked closer to the light extraction side than the first luminescence portion can also be suitably stacked in consideration of an interference condition. Here, i represents the number of the luminescence portion counted from the side of the reflective electrode.

An optical path length between the emission position of the i-th luminescence portion 305 and the light extraction-side reflective surface of the semi-reflective electrode is represented by L1(i), and an optical path length between the emission position of the i-th luminescence portion and the reflective surface of the reflective electrode is represented by L2(i). In addition, the peak wavelength of the multiple beam interference spectrum of an emission layer in the i-th luminescence portion is represented by λ(i). In this case, the display apparatus is formed so that light reflected at the semi-reflective electrode 4 may satisfy the following relationship (3) and light transmitting through the semi-reflective electrode 4 and reflected at the reflective electrode 2 may satisfy the following relationship (4):

k(i)−0.1≦2L1(i)/λ(i)+Φ/2π≦k(i)+0.1 (3)

k′(i)−0.1≦2L2(i)/λ(i)+δ/2π≦k′(i)+0.1 (4)

where δ represents a phase shift amount produced upon reflection of the light at the reflective electrode, Φ represents a phase shift amount produced upon reflection of the light at the semi-reflective electrode, and k(i) and k′(i) each represent a natural number.

With such constitution, light emitted from the i-th luminescence portion, the light reflected at the reflective electrode, and the light reflected at the semi-reflective electrode resonate with and intensify one another, whereby light with a wavelength λ(i) can be extracted at a high color purity and high luminance. In the Equations (3) and (4), when L1(i) and L2(i) each satisfy 2L1(i)/λ(i)+Φ/2π=k(i) and 2L2(i)/λ(i)+δ/2π=k′(i), light of wavelength λ(i) can be intensified most by interference.

In particular, as described above, light emitted from the first luminescence portion, which is disposed between the reflective electrode and the semi-reflective electrode, can be adjusted to light having a high color purity and high luminance by the resonator interposed between the reflective electrode and the semi-reflective electrode. In view of the foregoing, the characteristics of a blue light emitting device inferior in color purity and emission efficiency to red and green light emitting devices can be preferentially improved by: placing a blue emission layer in the first luminescence portion; and, defining, so as to satisfy the Equation (1), the L0 as an optical path length distance between a blue emission position and the reflective surface of the reflective electrode. Thus, an excellent full-color display apparatus can be realized. Further, when color purity and luminance of green are improved, a green emission layer is disposed in the first luminescence portion and the optical path length L0 and L are adjusted similarly as the blue emission layer is disposed.

Such optical path length adjustment as represented by the above Equations (3) and (4) has only to be performed as required for light emission from an luminescence portion except the first luminescence portion; the adjustment is preferably performed for all layers because an additional improvement in device performance can be expected.

As described above, the light beams A, B, and C can intensify one another by interference when the first luminescence portion is designed so that the L0 and L may satisfy the above Equations showing interference conditions. Thus, such optical design that light which one wishes to extract can be efficiently extracted can be easily performed.

The above optical path length adjustment can be performed by designing the thickness of each luminescence portion. In addition, the optical path length L1(i) and L2(i) can be suitably adjusted by providing each electrode with such internal constitution that a substance having a small optical absorption coefficient is interposed between transparent electrodes to serve as an optical path length adjustment layer. For example, quartz can be used as such substance having a small optical absorption coefficient, but the substance is not particularly limited.

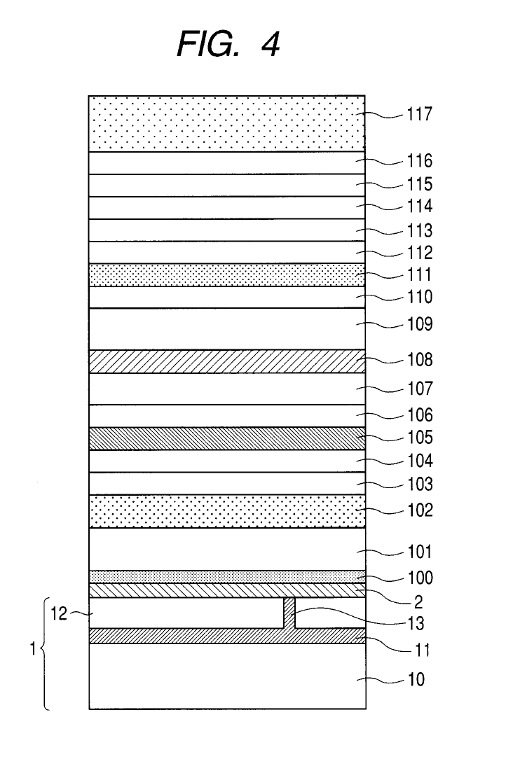

For example, in the case of the two-layer stacked constitution illustrated in FIG. 1, a blue emission layer can be stacked so that k(1)=1 is satisfied in the relationship (3), and a red or green emission layer can be stacked so that k(2)=2 is satisfied in the relationship. Further, in the case of a three-layer stacked constitution illustrated in FIG. 4, a blue emission layer can be stacked so that k(1)=1 is satisfied in the relationship (3), a green emission layer can be stacked so that k(2)=2 is satisfied in the relationship, and a red emission layer can be stacked so that k(3)=3 is satisfied in the relationship. The number of stacked layers and the value for the k(i) are not particularly limited as long as the following relationship is satisfied: k(1)<k(2)<k(3) . . . <k(n).

In addition, an emission color in an i-th luminescence portion (i≧2) in a display apparatus using a multilayer stacked organic EL device is not particularly limited. However, as described below, from the viewpoint of the maintenance of the view angle characteristic of the display apparatus, emission layers are more preferably stacked from a reflective electrode side in order of increasing peak wavelength of light to be extracted.

The view angle characteristic and the value for the k(i) have the following relationship: the smaller the k(i), the better the view angle characteristic. That is, when an emission position is viewed from an oblique direction at an angle of θ radians, the Equation (3) is changed into the following equation:

k(i)−0.1≦2L1(i)·cos θ/(λ(i)−Δλ(i))+Φ/2π≦k(i)+0.1 Eq. (5)

where Δλ(i) represents the shift amount of the peak wavelength of an emission spectrum when the emission position is viewed from the oblique direction at an angle of θ with respect to a peak wavelength λ(i) of the emission spectrum when the emission position is viewed from the front surface of the display apparatus. The following equation can be derived from the Equation (5), and shows that the smaller the k(i), the smaller the Δλ(i).

λ(i)−2L1(i)·cos θ/(k(i)−Φ/2π−0.1)≦Δλ(i)≦λ(i)−2L1(i)·cos θ/(k(i)−Φ/2π+0.1) Eq. (6)

As described above, the smaller the k(i), the more sufficient a color reproduction range that can be secured in a wide view angle. As an emission peak wavelength increases, the value for the ki tends to increase. Accordingly, the following procedure can lead to the improvement of the view angle characteristic: an emission layer having a shorter emission wavelength is placed closer to the reflective electrode 2. In a three-layer stacked system, blue, green, and red emission layers are preferably placed in the order closer to the reflective electrode 2.

Hereinafter, a light emitting display apparatus according to the present invention is specifically described with reference to the figures. FIG. 4 is an outline sectional view of an organic EL device of which a top emission type, active matrix organic EL display apparatus is formed. The substrate 1 is formed of the support 10, the TFT driver circuit 11, and the planarization passivation layer 12. A reflective electrode layer is formed on the substrate. The reflective electrode layer is formed of the reflective electrode 2 and a transparent conductive film 100. the reflective electrode 2 is composed of material has a reflectance at an interface with the transparent conductive film 100 of 50% or more, or preferably 80% or more. Although the metal is not particularly limited, silver, aluminum, chromium (a silver alloy or an aluminum alloy is also permitted), or the like is used. In addition, the reflective electrode 2 has only to be capable of injecting a hole into a hole transport layer 101, and no particular problem arises even when the reflective electrode is free of any transparent electrode as long as the reflective electrode can directly inject the hole.

Role of the transparent conductive film 100 is to improve hole injection property to the hole transport layer 101. Further, it is necessary that light toward the reflection electrode 2 and light reflected by the reflection electrode 2 are transmitted as much as possible. For that purpose, the transparent conductive film has a transmittance for visible light of 80 to 100%. To be more specific, the transparent conductive film desirably has a complex refractive index κ of 0.05 or less, or preferably 0.01 or less because of the following reason: the complex refractive index κ indicates the extent to which the transparent conductive film absorbs the visible light, and setting the κ to a small value can suppress the attenuation of the visible light due to multiple reflection. An oxide conductive film, specifically, for example, a compound film (ITO) of indium oxide and tin oxide or a compound film (IZO) of indium oxide and zinc oxide can be used as the transparent conductive film 100. The thickness of the transparent conductive film in the present invention is desirably set so that the thickness of the hole transport layer 101 may fall within the range of 10 to 200 nm, or preferably 10 to 100 nm, though the desirable value depends on the refractive index of the transparent conductive film and an emission color of the display apparatus. This is because driving the display apparatus as low a voltage as possible is advantageous from the viewpoint of power consumption.

An organic compound to be used in each of the hole transport layer (HTL) 101, an emission layer (EML) 102, an electron transport layer (ETL) 103, and an electron injection layer (EIL) 104 may be formed of either or both of a low-molecular weight material and a polymer material, and the constitution of the organic compound is not particularly limited. Any conventionally known material can be used as required. Examples of such compound are given below.

A hole transporting material preferably has excellent mobility for facilitating injection of a hole from an anode and for transporting the injected hole to an emission layer. The hole injection layer may be interposed between the anode and the hole transport layer Any known fluorescent dye or phosphorescent material having high emission efficiency may be used as an emission material.

The electron transporting material may be arbitrarily selected from materials which transports the injected electron into the emission layer. The material is selected in consideration of, for example, the balance with the mobility of a carrier of the hole transport material.

Further, any one of the above-mentioned electron transportable materials is caused to contain 0.1 percent to several tens of percent of an alkali metal or an alkaline earth metal, or a compound of any such metal, whereby electron-injection property can be imparted to the material, and the material can serve as an electron injection material. An electron injection layer 104 is not an indispensable layer, but, in consideration of damage upon subsequent formation of the semi-reflective electrode 105, an electron injection layer having a thickness of about 10 to 100 nm is desirably inserted in order that good electron-injection property may be secured.

The layer formed of an organic compound of the present invention can be formed by a vacuum vapor deposition method, an ionized vapor deposition method, sputtering, plasma, or a known coating method in which a compound is dissolved in an appropriate solvent. For example, a spin coating, dipping, casting, LB, and an inkjet method are exemplified. In film formation by a coating method, in particular, a film may be formed by using a compound in combination with an appropriate binder resin. The binder resin may be selected from a wide variety of binder resins.

Role of the semi-reflective electrode 105 is to satisfactorily inject electrons into the electron injection layer 104 and to reflect a part of light emitted from the emission layer 102 and to transmit a part of the light. For that purpose, it is preferable that the semi-reflective electrode 105 has 20% to 80% of transmittance with respect to a visible light and has reflectance at the interface of the electron injection layer 104 and at the interface of the hole injection layer 106 are 10% to 50%.

A metal element such as aluminum, silver, magnesium, or calcium, or an alloy of the metal element can be used in the semi-reflective electrode 105. In particular, an alloy of silver and magnesium (silver magnesium) is preferable from the viewpoints of electron injection property and a reflectance for emitted light. In addition, the thickness of the semi-reflective electrode is preferably selected from the range of, for example, 2 nm or more to 50 nm or less from the viewpoint that a desired transmittance property and reflection property can be easily obtained.

The above-mentioned oxide conductive film made of, for example, ITO or IZO can be used as a transparent electrode 111. A combination of the electron transport layer 103 and the electron injection layer 104, and a combination of an electron transport layer 109 and an electron injection layer 110 are desirably selected as appropriate so that good electron injection property may be obtained. In addition, each electrode can be formed by sputtering.

In addition, a protective layer may be provided for the uppermost layer of the display apparatus for the purpose of preventing the display apparatus from contacting oxygen, moisture, or the like. Examples of the protective layer include: a metal nitride film made of, for example, silicon nitride or silicon oxynitride; a metal oxide film made of, for example, tantalum oxide; and a diamond thin film; or a fluorine resin. In addition, the examples include: a polymer film made of, for example, a poly(p-xylene), polyethylene, a silicone resin, or a polystyrene resin; and a photocurable resin.

In addition, each device itself can be covered with, for example, glass, a gas impermeable film, or a metal, and packaged with a proper sealing resin. In addition, a moisture absorbent may be incorporated into the protective layer for improving the moisture resistance of the layer.

Although description has been given here by taking an EL device having the so-called double hetero constitution as an example, the present invention is applicable to an EL device having a single hetero constitution as well. Hereinafter, the present invention is described more specifically by way of examples. However, the present invention is not limited to these examples.

### Example 1

Example 1 in the present invention relates to a three-layer stacked display apparatus having the constitution illustrated in FIG. 4. In the display apparatus, a first luminescence portion, a second luminescence portion, and a third luminescence portion were stacked so as to include a blue emission layer, a green emission layer, and a red emission layer, respectively, and the first luminescence portion was adjusted to satisfy the interference condition Equations (1) and (2).

On a glass support 10 serving as a support, a TFT driver circuit 11 made of a low temperature polysilicon was formed. Then, a planarization passivation layer 12 made of acrylic resin was formed thereon, whereby a substrate 1 was obtained. Then, on the substrate, a silver alloy (AgPdCu) serving as a reflective electrode 2 was formed and patterned into a thickness of approximately 100 nm by sputtering. Further, ITO serving as a transparent conductive film 100 was formed and patterned into a thickness of 100 nm by sputtering, whereby an anode was formed. The anode was subjected to ultrasonic cleaning with isopropyl alcohol (IPA), then to boiling cleaning, and followed by drying. Further, after UV/ozone cleaning, an organic compound was formed into a film by vacuum vapor deposition.

Next, as a hole transport layer 101, Compound (I) represented by the following structural formula was formed into a film having a thickness of 49 nm. At that time, a degree of vacuum was 1×10⁻⁴ Pa and a deposition rate was 0.3 nm/sec.

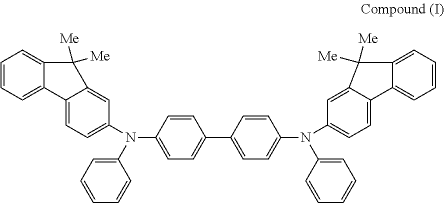

Next, as an emission layer 102, a blue emission layer was formed using shadow masks. As the blue emission layer, co-deposition from vapor (weight ratio of 80:20) was performed using Compound (II) as a host and light emitting Compound (III) both shown in the following structure formulae, so that an emission layer 102 having a thickness of 28 nm was formed. The layer was formed at a degree of vacuum at the time of the vapor deposition of 1×10⁻⁴ Pa and a film formation rate of 0.1 nm/sec.

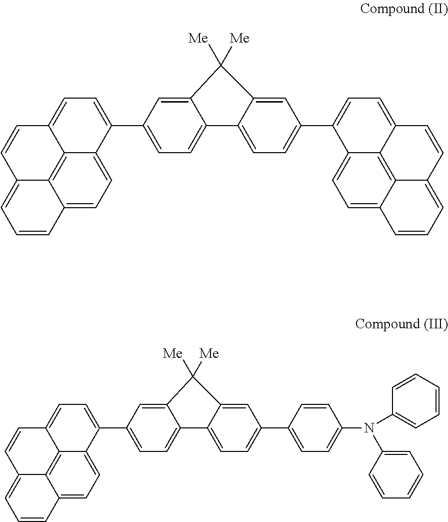

Further, bathophenathroline (Bphen) was formed into a film having a thickness of 24 nm by the vacuum vapor deposition method, which serves as an electron transport layer 103. The layer was formed at a degree of vacuum at the time of the vapor deposition of 1×10⁻⁴ Pa and a film formation rate of 0.3 nm/sec.

Next, Bphen and Cs₂CO₃ were co-deposited from the vapor (at a weight ratio of 90:10), whereby an electron injection layer 104 having a thickness of 27 nm was formed using a shadow mask. The layer was formed at the degree of vacuum at the time of the vapor deposition of 3×10⁻⁴ Pa and a film formation rate of 0.2 nm/sec.

The substrate on which the layers including the electron injection layer had been formed was transferred to a sputtering apparatus without the breakage of a vacuum. Then, Ag was formed into a film having a thickness of 5 nm, and furthermore, ITO was formed into a film having a thickness of 84 nm with a shadow mask. Those electrodes were integrated into a semi-reflective electrode 105.

Next, the resultant was transferred to a vapor deposition apparatus without the breakage of a vacuum, and GaPc was formed into a film having a thickness of 2 nm for each pixel to serve as a hole injection layer 106. At that time, a degree of vacuum was 1×10⁻⁴ Pa, and a deposition rate was 0.1 nm/sec.

Next, Compound (I) represented by the above structural formula was formed into a film having a thickness of 54 nm to serve as a hole transport layer 107. At that time, a degree of vacuum was 1×10⁻⁴ Pa, and a deposition rate was 0.3 nm/sec.

Next, a green emission layer was formed with a shadow mask to serve as an emission layer 108. Alq3 as a host and a luminous compound coumarin 6 were co-deposited from the vapor (at a weight ratio of 99:1), whereby the emission layer having a thickness of 38 nm was provided as a green emission layer. The layer was formed at a degree of vacuum at the time of the vapor deposition of 1×10⁻⁴ Pa and a film formation rate of 0.1 nm/sec.

Next, bathophenanthroline (Bphen) was formed into a film having a thickness of 20 nm to serve as an electron transport layer 109 by a vacuum vapor deposition method. The vapor deposition was performed under the following conditions: a degree of vacuum of 1×10⁻⁴ Pa and a film formation rate of 0.3 nm/sec.

Next, Bphen and Cs₂CO₃ were co-deposited from the vapor (at a weigh ratio of 90:10) with a shadow mask, whereby a film having a thickness of 39 nm to serve as an electron injection layer 110 was formed. The vapor deposition was performed under the following conditions: a degree of vacuum of 3×10⁻⁴ Pa and a film formation rate of 0.2 nm/sec.

The substrate on which the layers including the electron injection layer had been formed was transferred to a sputtering apparatus without the breakage of a vacuum. Then, ITO was formed into a film having a thickness of 54 nm with a shadow mask to serve as a transparent electrode 111.

Next, the resultant was transferred to a vapor deposition apparatus without the breakage of a vacuum, and GaPc was formed into a film having a thickness of 2 nm for each pixel to serve as a hole injection layer 112. At that time, a degree of vacuum was 1×10⁻⁴ Pa, and a deposition rate was 0.1 nm/sec.

Next, Compound (I) represented by the above structural formula was formed into a film having a thickness of 120 nm to serve as a hole transport layer 113. At that time, a degree of vacuum was 1×10⁻⁴ Pa, and a deposition rate was 0.3 nm/sec.

Next, as an emission layer 114, a red emission layer is formed using a shadow mask. As a red emission layer, Alq3 as a host and a luminous compound DCM [4-(dicyanomethylene)-2-methyl-6(p-dimethylaminostyryl)-4H-pyran] were used. These were co-deposited from the vapor (at a weight ratio of 99:1) and the emission layer having a thickness of 26 nm was formed.

Next, bathophenanthroline (Bphen) was formed into a film having a thickness of 20 nm to serve as a electron transport layer 115 by a vacuum vapor deposition method. The vapor deposition was performed under the following conditions: a degree of vacuum of 1×10⁻⁴ Pa and a film formation rate of 0.3 nm/sec.

Next, Bphen and Cs₂CO₃ were co-deposited from the vapor (at a weigh ratio of 90:10) with a shadow mask, whereby a film having a thickness of 42 nm to serve as an electron injection layer 116 was formed. The vapor deposition was performed under the following conditions: a degree of vacuum of 3×10⁻⁴ Pa and a film formation rate of 0.2 nm/sec.

The substrate on which the layers including the electron injection layer had been formed was transferred to a sputtering apparatus without the breakage of a vacuum. Then, ITO was formed into a film having a thickness of 63 nm with a shadow mask to serve as a light extraction electrode 117, whereby a display apparatus was obtained.

Table 1 shows a summary of design values for the display apparatus thus obtained. The display apparatus of this example uses the first emission layer 102 as a blue emission layer, the second emission layer 108 as a green emission layer, and the third emission layer 114 as a red emission layer, and the thickness of each luminescence portion is adjusted to an optimum value so that light emitted toward the reflective electrode 2 may satisfy the interference conditions.

TABLE 1

| | First emission | Second | Third emission |
|---|---|---|---|
| | layer | emission layer | layer |
| | Blue | Green | Red |
| ITO | 84 nm | 54 nm | 63 nm |
| Ag | 5 nm | — | — |
| EIL | 27 nm | 39 nm | 42 nm |
| ETL | 24 nm | 20 nm | 20 nm |
| EML | 28 nm | 38 nm | 26 nm |
| HTL | 49 nm | 54 nm | 120 nm |
| HIL | — | 2 nm | 2 nm |

With regard to the interference conditions, reference was made to design values in cases different from one another in the peak wavelength of a multiple beam interference spectrum and an order m shown in Table 2 below.

TABLE 2

| | Peak wavelength of | | |
|---|---|---|---|
| | multiple beam | | |
| | interference spectrum | | |
| | (nm) | | |
| | Blue | Green | Red |
| | 450 | 520 | 620 |
| m = 1 (λ/4 design) | 112.5 | 130 | 155 |
| m = 2 (3λ/4 design) | 337.5 | 390 | 465 |
| m = 3 (5λ/4 design) | 562.5 | 650 | 775 |

It should be noted that an interface between the emission layer and the electron transport layer was defined as an emission position for a blue color, and an interface between the emission layer and the hole transport layer was defined as an emission position for each of green and red colors. An optical path length is represented as the product of the refractive index of each layer and the thickness of the layer. Table 3 below shows the wavelength dependence of the refractive index of each layer.

TABLE 3

| Wave- | | | | | | | |
|---|---|---|---|---|---|---|---|
| length | | | | | | | |
| (nm) | HTL | B_EML | G_EML | R_EML | ETL | EIL | ITO |
| 440 | 1.92 | 1.93 | 2.01 | 2.03 | 1.79 | 1.81 | 1.94 |
| 450 | 1.89 | 1.89 | 1.96 | 1.98 | 1.77 | 1.79 | 1.92 |
| 460 | 1.87 | 1.86 | 1.92 | 1.95 | 1.75 | 1.77 | 1.92 |
| 510 | 1.83 | 1.79 | 1.82 | 1.85 | 1.70 | 1.72 | 1.84 |
| 520 | 1.82 | 1.78 | 1.81 | 1.84 | 1.69 | 1.72 | 1.83 |
| 530 | 1.82 | 1.78 | 1.81 | 1.83 | 1.69 | 1.71 | 1.81 |
| 610 | 1.79 | 1.75 | 1.77 | 1.78 | 1.66 | 1.69 | 1.71 |
| 620 | 1.79 | 1.74 | 1.77 | 1.78 | 1.66 | 1.69 | 1.7 |
| 630 | 1.79 | 1.74 | 1.77 | 1.77 | 1.66 | 1.68 | 1.68 |

The display apparatus of this example used the first emission layer 102 as a blue emission layer, the second emission layer 108 as a green emission layer, and the third emission layer 114 as a red emission layer, and the thickness of the first luminescence portion was adjusted to an optimum value so that the Equations (1) and (2) might be satisfied for causing the first luminescence portion to serve as a resonator.

In this example, values determined for an optical path length from the reflective electrode 2 to the semi-reflective electrode 4 and an optical path length distance from the emission surface of the first luminescence portion 3 to the reflective electrode 2 are as shown below. It should be noted that an interface between the emission layer and the electron transport layer was defined as an emission position.

Stacked material constitution from reflective electrode 2 to semi-reflective electrode 4:

ITO+HTL+EML+ETL+EIL

As the equation L=1.92×100+1.89×49+1.89×28+1.77×24+1.79×27=428.3=(450/2)×(m′−1) shows, m′=2.90 is satisfied, so the value for the optical path length is substantially a natural number multiple of the design peak wavelength λ.

Stacked material constitution from reflective electrode to emission surface: ITO+HTL+EML

As the equation Lb=1.92×100+1.89×49+1.89×28=337.5=112.5×(2m−1) shows, m=2.00 is satisfied, so the value for the optical path length is substantially three quarters of the design peak wavelength.

Table 4 shows a color reproduction range (NTSC ratio) emitted by the display apparatus and a power consumption (unit: mW) when the display apparatus displayed a white color on its entire surface at 100 cd/cm².

TABLE 4

| | |
|---|---|
| Color reproduction range | 96% |
| Power consumption (mW) | 334 |

### Comparative Example 1

Meanwhile, the display apparatus was changed as follows: in FIG. 4, the first emission layer 102 was used as a red emission layer, the second emission layer 108 was used as a green emission layer, and the third emission layer 114 was used as a blue emission layer. Further, the thickness of each luminescence portion was adjusted to an optimum value so that the interference condition equations for light emitted toward the reflective electrode 2 might be satisfied. Except the foregoing, a display apparatus was produced in the same manner as in Example 1, and was defined as a comparative example. Table 5 shows a summary of design values for the display apparatus of the comparative example.

TABLE 5

| | First | Second | Third |
|---|---|---|---|
| | emission | emission | emission |
| | layer | layer | layer |
| | Red | Green | Blue |
| ITO | 87 nm | 93 nm | 90 nm |
| EIL | 39 nm | 37 nm | 44 nm |
| ETL | 20 nm | 20 nm | 20 nm |
| EML | 25 nm | 37 nm | 35 nm |
| HTL | 180 nm | 59 nm | 54 nm |
| HIL | — | 2 nm | 2 nm |

Table 6 shows a color reproduction range (NTSC ratio) emitted by the display apparatus and a power consumption (unit: mW) when the display apparatus displayed a white color on its entire surface at 100 cd/cm².

TABLE 6

| | |
|---|---|
| Color reproduction range | 64% |
| Power consumption (mW) | 447 |

From a comparison between Table 4 of this example and Table 6 of the comparative example shown above, it was found that the display apparatus of this example was able to show more excellent color reproducibility, a lower power consumption, and hence higher reliability than those of the display apparatus of the comparative example.

In addition, from a comparison between Table 4 of this example and Table 5 of Example 1, it was found that an additional improvement in color reproducibility was achieved in this example. In addition, the display apparatus of this example showed a good view angle characteristic when viewed from an oblique direction.

### Example 2

A display apparatus of Example 2 in the present invention was produced in the same manner as in Example 1 except that the second luminescence portion was designed so as to satisfy the Equations (3) and (4).

Table 7 shows a summary of design values for the display apparatus. The display apparatus of this example used the first emission layer 102 as a blue emission layer, the second emission layer 108 as a green emission layer, and the third emission layer 114 as a red emission layer, and the thickness of the first luminescence portion was adjusted to an optimum value so that the interference conditions might be satisfied for causing the first luminescence portion to serve as a resonator. Further, the thickness of the second luminescence portion was adjusted to an optimum value so that light emitted toward the first reflective electrode 2 might satisfy the interference condition equations. That is, as in the calculation example in Example 1, an optical path length is represented as the product of the refractive index of each layer and the thickness of the layer, and the thickness was selected so that the interference condition equations might be optimized.

TABLE 7

| | First | Second | Third |
|---|---|---|---|
| | emission | emission | emission |
| | layer | layer | layer |
| | Blue | Green | Red |
| ITO | 84 nm | 60 nm | 63 nm |
| Ag | 9 nm | — | — |
| EIL | 20 nm | 22 nm | 42 nm |
| ETL | 14 nm | 20 nm | 20 nm |
| EML | 28 nm | 36 nm | 26 nm |
| HTL1 | 52 nm | 68 nm | 120 nm |
| HIL | — | 2 nm | 2 nm |

Table 8 shows a color reproduction range (NTSC ratio) emitted by the display apparatus and a power consumption (unit: mW) when the display apparatus displayed a white color on its entire surface at 100 cd/cm².

TABLE 8

| | |
|---|---|
| Color reproduction range | 91% |
| Power consumption (mW) | 328 |

From a comparison between Table 8 of this example and Table 6 of the comparative example shown above, it was found that the display apparatus of this example was able to show more excellent color reproducibility and higher reliability than those of the display apparatus of the comparative example. In addition, the display apparatus of this example showed a good view angle characteristic when viewed from an oblique direction.

### Example 3

Example 3 in the present invention was a three-layer stacked display apparatus formed of three emission layers, i.e., red, green, and blue emission layers and having such constitution as shown in FIG. 4, and each layer was produced in the same manner as in Example 1.

Table 9 shows a summary of design values for the display apparatus. The display apparatus of this example used the first emission layer 102 as a blue emission layer, the second emission layer 108 as a green emission layer, and the third emission layer 114 as a red emission layer, and the thickness of the first luminescence portion was adjusted to an optimum value so that the interference conditions might be satisfied for causing the first luminescence portion to serve as a resonator. Further, the thickness of each of the second and third luminescence portions was adjusted to an optimum value so that the Equations (3) and (4) might be satisfied.

TABLE 9

| | First | Second | Third |
|---|---|---|---|
| | emission | emission | emission |
| | layer | layer | layer |
| | Blue | Green | Red |
| ITO | 85 nm | 83 nm | 91 nm |
| Ag | 10 nm | — | — |
| EIL | 20 nm | 20 nm | 49 nm |
| ETL | 14 nm | 20 nm | 20 nm |
| EML | 26 nm | 37 nm | 27 nm |
| HTL1 | 56 nm | 70 nm | 79 nm |
| HIL | — | 2 nm | 2 nm |

Table 10 shows a color reproduction range (NTSC ratio) emitted by the display apparatus and a power consumption (unit: mW) when the display apparatus displayed a white color on its entire surface at 100 cd/cm².

TABLE 10

| | |
|---|---|
| Color reproduction range | 93% |
| Power consumption (mW) | 315 |

From a comparison between Table 10 of this example and Table 6 of the comparative example shown above, it was found that the display apparatus of this example was able to show more excellent color reproducibility and higher reliability than those of the display apparatus of the comparative example.

In addition, from a comparison between Table 10 of this example and Table 8 of Example 2, it was found that the display apparatus of this example was able to show a lower power consumption and higher reliability than those of the display apparatus of Example 2. In addition, the display apparatus of this example showed a good view angle characteristic when viewed from an oblique direction.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Applications No. 2008-171745, filed Jun. 30, 2008, No. 2008-249881, filed Sep. 29, 2008, No. 2009-139375, filed Jun. 10, 2009, and No. 2009-155044, filed Jun. 30, 2009, which are hereby incorporated by reference herein in their entirety.

1. A light emitting display apparatus, comprising:
a substrate;
multiple luminescence portions stacked on the substrate in a direction perpendicular to a surface of the substrate, the multiple luminescence portions each being interposed between a pair of electrodes; and
a light extraction portion for extracting light emitted from the luminescence portions, wherein:
one of the luminescence portion, which is placed farthest from the light extraction portion, is interposed between a reflective electrode and a semi-reflective electrode; and
an optical path length between the reflective electrode and the semi-reflective electrode is set such that light extracted outside the light emitting display apparatus, among lights emitted from the luminescence portion between the reflective electrode and the semi-reflective electrode, is intensified by interference.

2. The light emitting display apparatus according to claim 1, wherein the optical path length between the reflective electrode and the semi-reflective electrode is formed to satisfy the following Equations (1) and (2):
m−0.1≦2L0/λ+δ/2π≦m+0.1 (1)
m′−0.1≦2L/λ+(δ+Φ)/2π≦m′+0.1 (2)
where L0 represents an optical path length between an emission position of the luminescence portion which is disposed between the reflective electrode and the semi-reflective electrode, and a reflective surface of the reflective electrode; L represents an optical path length between the reflective surface of the reflective electrode and a reflective surface of the semi-reflective electrode; λ represents a peak wavelength of the extracted light; δ represents a phase shift amount produced upon reflection of the extracted light at the reflective electrode; Φ represents a phase shift amount produced upon reflection of the extracted light at the semi-reflective electrode; and m and m′ each represent a natural number.

3. The light emitting display apparatus according to claim 1, wherein at least an i-th luminescence portion counted from a side of the reflective electrode, among the multiple luminescence portions, satisfies the following Equations (3) and (4):
k(i)−0.1≦2L1(i)/λ(i)+Φ/2π≦k(i)+0.1 (3)
k′(i)−0.1≦2L2(i)/λ(i)+δ/2π≦k′(i)+0.1 (4)
where L1 represents an optical path length between an emission position of the luminescence portion and the reflective surface in the semi-reflective electrode, L2 represents an optical path length between the emission position of the electroluminescent layer and the reflective surface in the reflective electrode, λ(i) represents a peak wavelength of light extracted from the electroluminescent layer, δ represents a phase shift amount produced upon reflection of the extracted light at the reflective electrode; Φ represents a phase shift amount produced upon reflection of the extracted light at the semi-reflective electrode; k(i) and k′(i) each represent a natural number, and i represents a number of the electroluminescent layer counted from a side of the reflective electrode, the number being a natural number of 2 or more.

4. The light emitting display apparatus according to claim 1, wherein the luminescence portion between the reflective electrode and the semi-reflective electrode includes a blue emission layer.
